(19) United States
(12) Patent Application Publication
(10) Pub. No.: US 2024/0243152 A1
(43) Pub. Date: Jul. 18, 2024

(54) SEMICONDUCTOR DEVICE AND METHOD FOR MANUFACTURING THE SAME

(71) Applicant: SK hynix Inc., Icheon-si (KR)

(72) Inventors: Jeong Mook CHOI, Icheon-si (KR); Kuem Ju LEE, Icheon-si (KR)

(21) Appl. No.: 18/345,421

(22) Filed: Jun. 30, 2023

(30) Foreign Application Priority Data
Jan. 18, 2023 (KR) 10-2023-0007188

(51) Int. Cl. H01L 27/146; H01L 23/00

(52) U.S. Cl. CPC H01L 27/14634; H01L 24/03; H01L 24/05; H01L 24/08; H01L 2224/034; H01L 2224/03614; H01L 2224/0508; H01L 2224/05124; H01L 2224/05147; H01L 2224/05166; H01L 2224/08145; H01L 2924/01013; H01L 2924/01029; H01L 2924/04941

(57) ABSTRACT

Disclosed is a method of manufacturing a semiconductor device, including: forming a first metal layer; forming a conductive layer on the first metal layer; forming a capping layer on the conductive layer; etching the first metal layer, the conductive layer, and the capping layer; depositing a bonding oxide layer; etching the bonding oxide layer and the capping layer; forming a first bonding metal layer in an etched space; and forming a second metal layer on the first bonding metal layer.

### CROSS REFERENCE TO RELATED APPLICATION

This patent document claims the priority and benefits of Korea Patent Application No. 10-2023-0007188, filed on Jan. 18, 2023, which is incorporated by reference in its entirety as part of the disclosure of this patent document.

### TECHNICAL FIELD

The disclosed technology relates to a semiconductor device and a method for manufacturing the same.

### BACKGROUND

For high integration of semiconductor devices, technologies for stacked semiconductor devices are being developed to reduce the area of a chip by integrating necessary circuits or devices on two substrates, an upper and lower substrate, and then bonding the two substrates.

Elements on the upper and lower substrates to be bonded must be electrically connected to each other, and hybrid bonding is used for this purpose.

### SUMMARY

The disclosed technology can be implemented in various implementations to provide designs of structures and methods of fabrication of semiconductor devices, including semiconductor imaging devices capable of preventing certain defects (e.g., a defect of having a pixel pattern noise (FPN)) due to by-products generated during a patterning process, and, more generally, semiconductor devices with components formed on two substrates that are bonded together. The disclosed technology may be used in various applications, including but not limited to, image sensing devices and other semiconductor devices.

In one aspect, a method of manufacturing a semiconductor device is provided. The method includes forming a first metal layer; forming a conductive layer on the first metal layer; forming a capping layer on the conductive layer; etching the first metal layer, the conductive layer, and the capping layer; depositing a bonding oxide layer; etching the bonding oxide layer and the capping layer; forming a first bonding metal layer in an etched space; and forming a second metal layer on the first bonding metal layer.

In some implementations, the first metal layer may include aluminum (Al). In some implementations, the conductive layer may include titanium nitride (TiN). In some implementations, the capping layer may include nitride. In some implementations, the second metal layer may include copper (Cu).

In another aspect, a semiconductor device is provided to include a lower substrate; and an upper substrate bonded onto a top of the lower substrate, and the lower substrate includes: a first metal layer; a conductive layer formed on the first metal layer; and a capping layer formed on the conductive layer. In another aspect, a semiconductor device is provided to comprise: a substrate, wherein the substrate comprises: a first metal layer; a conductive layer formed on the first metal layer without having any portion of the conductive layer disposed on a side of the first metal layer; and a capping layer formed on the conductive layer without having any portion of the capping layer disposed on a side of the first metal layer.

In some implementations, the lower substrate may further include a bonding oxide layer formed in a space where the first metal layer, the conductive layer, and the capping layer are etched. In some implementations, the lower substrate may further include a first bonding metal layer formed in a space where the bonding oxide layer and the capping layer are etched. In some implementations, the lower substrate may further include a second metal layer formed on the first bonding metal layer.

In another aspect, a semiconductor device is provided to include a first metal layer; a conductive layer formed on the first metal layer, and a capping layer formed on the conductive layer.

In some implementations, by a process of etching the first metal layer, the conductive layer, and the capping layer, the conductive layer may be formed on a top surface of the first metal layer and not on a side surface of the first metal layer. In some implementations, by the process of etching the first metal layer, the conductive layer, and the capping layer, the capping layer may be formed above the first metal layer and not on a side surface of the first metal layer. In some implementations, the substrate may further include a bonding oxide layer formed to contact a side surface of the first metal layer. In some implementations, the substrate may further include a first bonding metal layer formed to contact the conductive layer, the capping layer, and the bonding oxide layer. In some implementations, the substrate may further include a second metal layer formed to contact the first bonding metal layer.

### BRIEF DESCRIPTION OF THE DRAWINGS

FIG. 1 is a block diagram of an image sensing device based on an implementation of the disclosed technology.

FIG. 2 is a view illustrating a stacked structure of a semiconductor device based on an implementation of the disclosed technology for fabricating an imaging device as shown in FIG. 1 and other semiconductor devices.

FIG. 3 is a flowchart of a method for manufacturing a semiconductor device based on an implementation of the disclosed technology.

FIGS. 4 to 9 are views for explaining a method for manufacturing a semiconductor device based on an implementation of the disclosed technology.

### DETAILED DESCRIPTION

Features, and certain advantages in connection with specific implementations of the disclosed technology disclosed in this patent document are described by example with reference to the accompanying drawings. In this patent document, the same reference numerals will be used to refer to the same or similar elements throughout the specification.

During a conventional semiconductor device manufacturing process, by-products are generated during an etching of a hybrid bonding routing metal and such by-products attach to a side of aluminum (Al) to react with a solution in a subsequent process. The by-products are trapped in capping nitride and causes a reliability defect (e.g., the undesired pixel pattern noise (FPN) in an array of image sensing pixels of an imaging device) while progressively dissolving the aluminum (Al). Some implementations of the disclosed technology provide a semiconductor device and a method for manufacturing the semiconductor device, which is possible to suppress fixed-pattern noise (FPN) due to by-products generated during a patterning process. In some implementations, it is possible to suppress a reliability defect due to a reaction in which by-products generated in the patterning process progressively dissolve aluminum (Al). In some implementations, it is possible to secure diversity of an aluminum patterning (Al Patterning) structure.

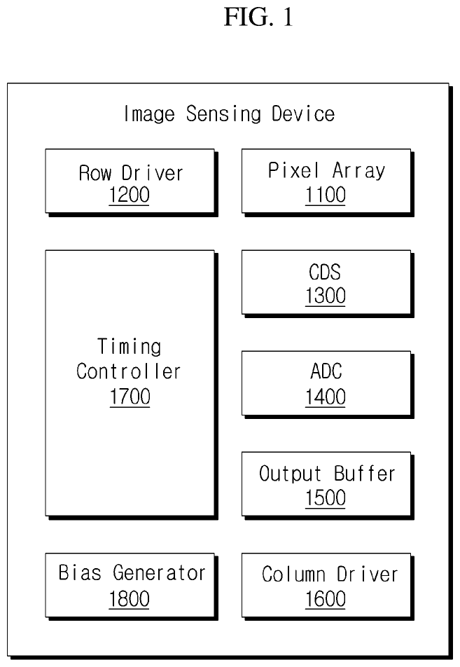

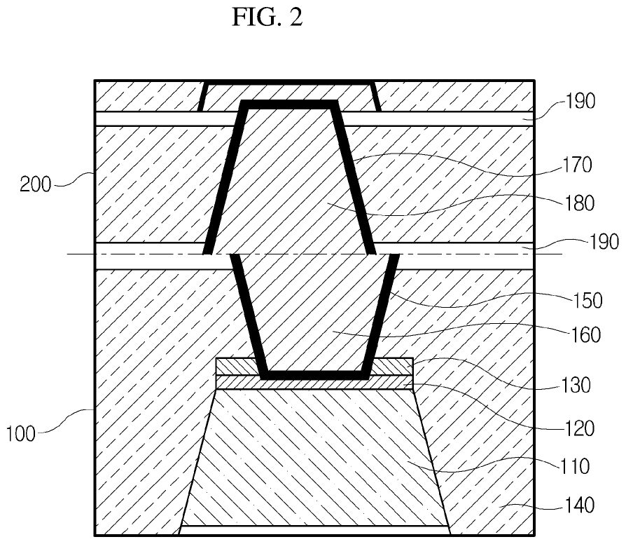

FIG. 1 is a block diagram of an image sensing device based on an embodiment of the disclosed technology. This image sensing device may be constructed based on the technology disclosed in FIGS. 2-9.

Referring to FIG. 1, the image sensing device according to an embodiment may include a pixel array 1100, a row driver 1200, a correlated double sampler (CDS) 1300, an analog-digital converter (ADC) 1400, an output buffer 1500, a column driver 1600, a timing controller 1700, and a bias generator 1800. The components of the image sensing device illustrated are discussed by way of example only, and this patent document encompasses additions or omissions of components as necessary.

The pixel array 1100 may include a plurality of pixels arranged in a plurality of rows and a plurality of columns. In one embodiment, the plurality of pixels can be arranged in a two-dimensional pixel array including rows and columns. In another example, the plurality of unit imaging pixels can be arranged in a three-dimensional pixel array. The plurality of pixels may convert an optical signal into an electrical signal on a unit pixel basis or on a pixel group basis and the pixels in a pixel group share at least certain internal circuitry. The pixel array 1100 may receive driving signals, including a row selection signal, a pixel reset signal and a transmission signal, from the row driver 1200. Upon receiving the driving signal, corresponding pixels in the pixel array 1100 may be activated to perform operations corresponding to the row selection signal, the pixel reset signal, and the transmission signal.

The row driver 1200 may activate the pixel array 1100 to perform certain operations on the pixels in the corresponding row based on commands and control signals provided by the timing controller 1700. In one embodiment, the row driver 1200 may select at least one pixel arranged in at least one row of the pixel array 1100. The row driver 1200 may generate a row selection signal to select at least one row among the plurality of rows. The row driver 1200 may sequentially enable the pixel reset signal and the transmission signal for the pixels corresponding to the at least one selected row. Thus, a reference signal and an image signal, which are analog signals generated by each of the pixels of the selected row, may be sequentially transferred to the CDS 1300. At this time, the reference signal may be an electrical signal that is provided to the CDS 1300 when a sensing node of a pixel (e.g., floating diffusion node) is reset, and the image signal may be an electrical signal that is provided to the CDS 1300 when photocharges generated by the pixel are accumulated in the sensing node. A reference signal representing reset noise inherent in a pixel and an image signal representing intensity of incident light may be collectively referred to as a pixel signal.

CMOS image sensors may use the correlated double sampling (CDS) to remove undesired offset values of pixels known as the fixed pattern noise by sampling a pixel signal twice to remove the difference between these two samples. In some embodiments, the correlated double sampling (CDS) may remove the undesired offset value of pixels by comparing pixel output voltages obtained before and after photocharges generated by incident light are accumulated in the sensing node so that only pixel output voltages based on the incident light can be measured. In one embodiment, the CDS 1300 may sequentially sample and hold the reference signal and the image signal, which are provided to each of a plurality of column lines from the pixel array 1100. That is, the CDS 1300 may sample and hold the reference signal and the image signal which correspond to each of the columns of the pixel array 1100.

The CDS 1300 may transfer the reference signal and the image signal of each of the columns as a correlate double sampling signal to the ADC 1400 based on control signals from the timing controller 1700.

The ADC 1400 is used to convert CDS signals into digital signals for each of the columns and output the digital signal. In one embodiment, the ADC 1400 may be implemented as a ramp-compare type ADC. The ramp-compare type ADC may include a comparator circuit for comparing the analog pixel signal with a ramp signal that ramps up or down over time, and a counter that performs a counting operation. In an example, the counter may perform the counting operation until the ramp signal matches the analog pixel signal. In another example, the counter may count the number of crossing points of the ramp signal and the analog pixel signal. In one embodiment, the ADC 1400 may convert the correlate double sampling signal generated by the CDS 1300 for each of the columns into a digital signal, and output the digital signal.

The ADC 1400 may include a plurality of column counters corresponding to each of the columns of the pixel array 1100. Each column of the pixel array 1100 is coupled to a column counter, and image data can be generated by converting the correlate double sampling signals corresponding to each of the columns into digital signals using the column counters. In another embodiment of the disclosed technology, the ADC 1400 may include a global counter to convert the correlate double sampling signals corresponding to each of the columns into digital signals using a global code provided from the global counter.

The output buffer 1500 may temporarily hold the column-based image data provided from the ADC 1400 to output the image data. The output buffer 1500 may temporarily store the image data output from the ADC 1400 based on control signals of the timing controller 1700. The output buffer 1500 may serve as an interface to compensate for data rate differences or transmission (or processing) rate differences between the image sensing device and other devices.

The column driver 1600 may select a column of the output buffer 1500 based on a control signal from the timing controller 1700, and sequentially output the image data, which are temporarily stored in the selected column of the output buffer 1500. In one embodiment, upon receiving an address signal from the timing controller 1700, the column driver 1600 may generate a column selection signal based on the address signal and select a column of the output buffer 1500, outputting the image data as an output signal from the selected column of the output buffer 1500.

The timing controller 1700 may control at least one among the row driver 1200, the CDS 1300, the ADC 1400, the output buffer 1500, the column driver 1600, and the bias generator 1800.

The timing controller 1700 may provide a clock signal required for the operations of the respective components of the image sensing device, a control signal for timing control, and address signals for selecting a row or column, a signal that controls a level of a bias voltage applied to the pixel array 1100, and others to at least one among the row driver 1200, the CDS 1300, the ADC 1400, the output buffer 1500, the column driver 1600 and the bias generator 1800. In an embodiment of the present disclosure, the timing controller 1700 may include a logic control circuit, a phase lock loop (PLL) circuit, a timing control circuit, a communication interface circuit and others.

The bias generator 1800 may generate a bias voltage for suppressing a dark current generated in pixels of the pixel array 1100 and supply the generated bias voltage to the pixel array 1100.

The bias voltage may be determined during a wafer probe test of the image sensing device and stored in a one-time programmable (OTP) memory. For example, the bias voltage may be experimentally determined as a value capable of maximizing a dark current suppression effect while minimizing unnecessary power consumption without impairing performance of the image sensing device.

The bias generator 1800 may generate a voltage corresponding to the bias voltage stored in the OTP memory. In an embodiment, the OTP memory may be included in the image sensing device, and in particular, may be included in the bias generator 1800.

In an embodiment, the bias voltage may include a plurality of values.

For example, the plurality of values may respectively correspond to a plurality of operation modes of the image sensing device. The dark currents generated at low light and the dark currents generated at high light levels may be different from each other, and the bias voltage provided by the bias generator 1800 to effectively suppress the dark currents in each environment may vary depending on a mode.

Alternatively, the plurality of values may respectively correspond to a plurality of areas of the pixel array 1100. The dark currents generated may be different from each other according to positions of the pixel in the pixel array 1100, and the bias voltage provided by the bias generator 1800 to effectively suppress the dark current regardless of the position of the pixel may vary depending on the regions of the pixel array 1100.

The bias voltage may be a negative voltage having a negative sign, but other implementations are also possible.

FIG. 2 is a view illustrating a stacked structure of a semiconductor device based on an embodiment of the disclosed technology. This stacked structure can be used to construct an imaging device as shown in FIG. 1 and other semiconductor devices.

Referring to FIG. 2, a semiconductor device based on an exemplary embodiment of the disclosed technology includes a lower substrate 100 and an upper substrate 200.

In an embodiment, the lower substrate 100 may be bonded onto the upper substrate 200 through, for example, a hybrid bonding technology.

In an embodiment, the lower substrate 100 may include a first metal layer 110, a conductive layer 120, a capping layer 130, a bonding oxide layer 140, a first bonding metal layer 150, and a second metal layer 160.

In an embodiment, the first metal layer 110 may be formed through a process of depositing aluminum (Al).

In an embodiment, by a process of etching the first metal layer 110, the conductive layer 120, and the capping layer 130, a side surface of the first metal layer 110 may be in contact with the bonding oxide layer 140, and a top surface of the first metal layer 110 may be in contact with the conductive layer 120.

In an embodiment, the conductive layer 120 may be formed on a top surface of the first metal layer 110.

In an embodiment, the conductive layer 120 may be formed through a process of depositing titanium nitride (TiN) on the first metal layer 110.

In an embodiment, by a process of etching the first metal layer 110, the conductive layer 120, and the capping layer 130, the conductive layer 120 may be formed on a top surface of the first metal layer 110. In the specific example as illustrated in FIG. 2, the entire conductive layer 120 may be formed only on the top surface of the first metal layer 110 without having any portion of the conductive layer 120 on a side surface of the first metal layer 110.

In an embodiment, the capping layer 130 may be formed on a top surface of the conductive layer 120.

In an embodiment, the capping layer 130 may be formed through a process of depositing a capping nitride layer on the conductive layer 120, before etching the first metal layer 110, the conductive layer 120, and the capping layer 130.

By forming a capping nitride layer on the conductive layer 120 before etching the first metal layer 110, the conductive layer 120, and the capping layer 130, it is possible to suppress fixed pattern noise (FPN) caused by by-products generated during an etching process. In addition, since by-products generated in the etching process are prevented from being trapped even when by-products attach to a side surface of the first metal layer 110, reliability defects due to a reaction in which the by-products progressively dissolve aluminum (Al) may be suppressed. In addition, diversity can be secured in an aluminum patterning (Al Patterning) structure.

In an embodiment, by the process of etching the first metal layer 110, the conductive layer 120, and the capping layer 130, the capping layer 130 may be formed above the first metal layer 110. In the example, the entire capping layer 130 may be formed on the top surface of the first metal layer without having any portion of the capping layer 130 on a side surface of the first metal layer 110.

In an embodiment, the bonding oxide layer 140 may be formed through a process of depositing a bonding oxide layer after performing forming the capping layer 130 and then etching the first metal layer 110, the conductive layer 120, and the capping layer 130 to provide an etched structure.

In an embodiment, the bonding oxide layer 140 may be formed to cover the etched structure. In the example, the bonding oxide layer 140 may be formed to contact a side surface of the first metal layer 110, a side surface of the conductive layer 120, and a side surface and a top surface of the capping layer 130.

In an embodiment, the first bonding metal layer 150 may be formed through a process of depositing a barrier metal (BM) in a space formed by etching the bonding oxide layer 140 and the capping layer 130.

In an embodiment, the first bonding metal layer 150 may be formed to contact the conductive layer 120, the capping layer 130, and the bonding oxide layer 140.

In an embodiment, the second metal layer 160 may be formed on the first bonding metal layer 150 in a space formed by etching the bonding oxide layer 140 and the capping layer 130.

In an embodiment, the second metal layer 160 may be formed through a process of depositing copper (Cu) on the first bonding metal layer 150.

In an embodiment, the second metal layer 160 may be formed to contact the first bonding metal layer 150.

In an embodiment, the upper substrate 200 may be bonded onto a surface of the lower substrate 100 through, for example, the hybrid bonding technology. The surface of the lower substrate 100 bonded to the upper substrate 200 may be referred to as a top surface of the lower substrate 100.

In an embodiment, the upper substrate 200 may include a second bonding metal layer 170 and a third metal layer 180.

In an embodiment, the second bonding metal layer 170 may be formed through etching and depositing a barrier metal (BM) in the same or similar manner as a process of forming the first bonding metal layer 150.

In an embodiment, the third metal layer 180 may be formed through processes of etch and depositing copper (Cu) in the same or similar manner as a process of forming the second metal layer 160.

In an embodiment, the third metal layer 180 may be formed to have one side in contact with the second metal layer 160 of the lower substrate 100 and the other side in contact with the bonding oxide layer 140 of the lower substrate 100. The contact between the third metal layer 180 in the upper substrate 200 and the second metal layer 160 of the lower substrate 100 can be used to provide an electrical conductive path between circuits or components formed on the two substrates 100 and 200.

A bonding layer 190 may be provided to function as a junction interface area. In the example, the bonding layer 190 may include nitride.

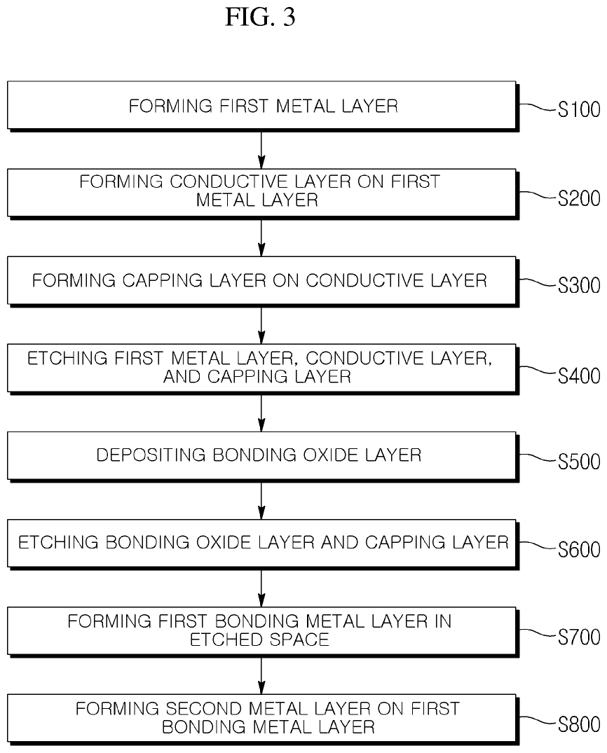

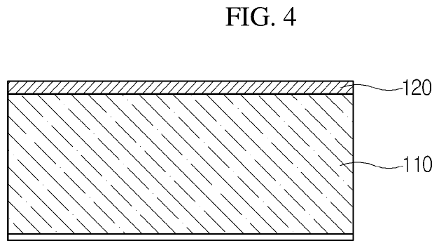

FIG. 3 is a flowchart of a method for manufacturing a semiconductor device based on an embodiment of the disclosed technology. FIGS. 4 to 9 are views for explaining a method for manufacturing a semiconductor device based on an embodiment of the disclosed technology.

Referring to FIG. 3, a method for manufacturing a semiconductor device based on an embodiment of the disclosed technology is described. The method may include forming the first metal layer 110 (S100) and forming the conductive layer 120 on the first metal layer 110 (S200), forming the capping layer 130 on the conductive layer 120 (S300), etching the first metal layer 110, the conductive layer 120, and the capping layer 130 (S400), depositing the bonding oxide layer 140 (S500), etching the bonding oxide layer 140 and the capping layer 130 (S600), forming the first bonding metal layer 150 in the etched space (S700), and forming the second metal layer 160 on the first bonding metal layer 150 (S800). The manufacturing steps may be discussed with reference to FIGS. 4-9.

Referring to FIGS. 3 and 4, the first metal layer 110 may be formed at S100 and the conductive layer 120 may be formed over the first metal layer 110 at S200. For example, the first metal layer 110 may be formed through a process of depositing aluminum (Al) on the substrate. For example, the conductive layer 120 may be formed through the process of depositing titanium nitride (TiN) on the first metal layer 110.

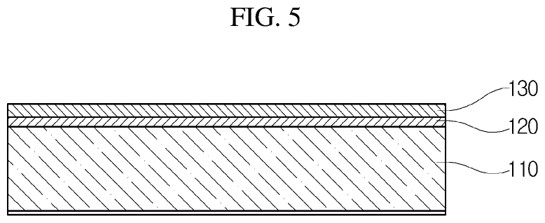

Referring to FIGS. 3 and 5, at S300, the capping layer 130 may be formed on the conductive layer 120. In the example, the capping layer 130 may be formed through the process of depositing the capping nitride layer on the conductive layer 120, before etching the first metal layer 110, the conductive layer 120, and the capping layer 130.

By forming a capping nitride layer on the conductive layer 120 before etching the first metal layer 110, the conductive layer 120, and the capping layer 130, it is possible to suppress fixed pattern noise (FPN) caused by by-products generated in the etching process. In addition, since by-products generated in the etching process are prevented from being trapped even when by-products attach to a side surface of the first metal layer 110, reliability defects due to a reaction in which the by-products progressively dissolve aluminum (Al) can be suppressed.

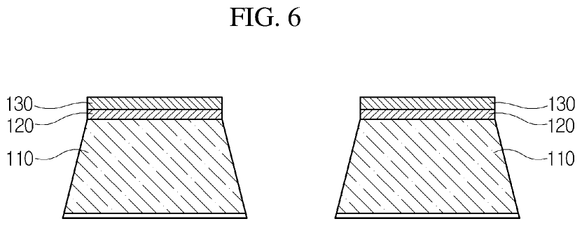

Referring to FIGS. 3 and 6, at S400, the first metal layer 110, the conductive layer 120, and the capping layer 130 may be etched. By etching the first metal layer 110, the conductive layer 120 and the capping layer 130 using a mask to form a desired etched pattern such as the pattern shown in FIG. 6. The capping layer 130 may be formed above the first metal layer 110. In the example as illustrated in FIG. 6, the capping layer 130 may be formed only on the first metal layer 110.

The etch process may be performed by using a high density plasma (HDP) etch system such as inductively coupled plasma (ICP), decoupled plasma source (DPS), and electron cyclotron resonance (ECR) systems, and as an etching gas, one of BCl₃, CₓF_{y} (x and y are natural numbers), NFₓ (x is a natural number), SFₓ (x is a natural number) gas (each flow rate is 10 to 50 sccm) and Cl₂ (flow rate is 50 to 200 sccm) or a gas mixture thereof is used. To form the vertical profile, a source power ranging from 500 W to 2,000 W is applied and an additive gas is used, wherein the additive gas includes one of O₂ gas flowing at a rate of 1 sccm to 20 sccm, nitrogen (N₂) gas flowing at a rate of 1 sccm to 100 sccm, argon (Ar) gas flowing at a rate of 50 sccm to 200 sccm, helium (He) gas flowing at a rate of 50 sccm to 200 sccm, and a gas mixture thereof.

The capping nitride layer is formed by using an etching gas, for example, NF₃, CF₄, SF₆, Cl₂, O₂, Ar, He, HBr, N₂ gas.

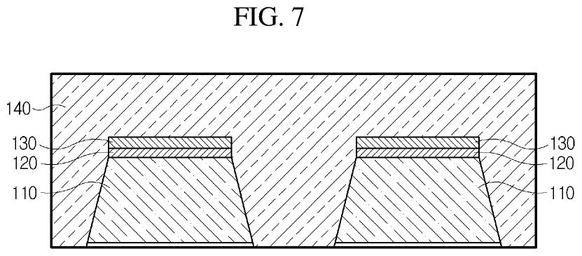

Referring to FIGS. 3 and 7, at S500, the bonding oxide layer 140 may be formed. For example, the bonding oxide layer 140 may be formed through the process of depositing the bonding oxide layer in a space formed by etching the first metal layer 110, the conductive layer 120, and the capping layer 130 so that various components in the etched pattern shown in FIG. 6 are embedded in, and held together by, the bonding oxide layer 140.

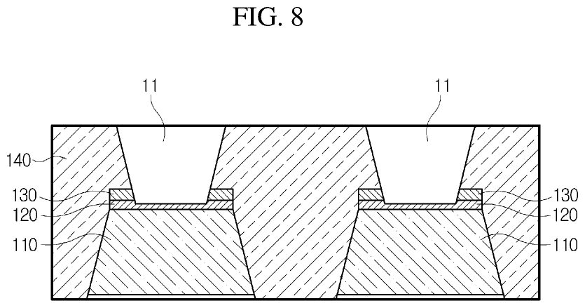

Referring to FIGS. 3 and 8, at S600, the bonding oxide layer 140 and the capping layer 130 may be etched to form trenches to expose the conductive layer 120 at various components for forming conductive contacts. For example, by etching the bonding oxide layer 140 and the capping layer 130 using a mask, one or more trenches or spaces 11 may be formed above the first metal layer 110 to expose the conductive layer 120 and the second metal layer 160 can be deposited into the one or more trenches or spaces 11.

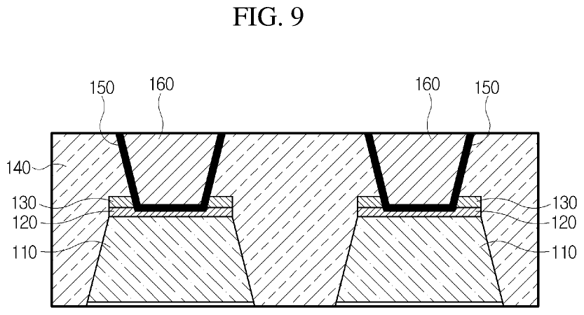

Referring to FIGS. 3 and 9, at S700, the first bonding metal layer 150 (S700) may be formed before depositing the second metal layer 160. For example, by depositing the barrier metal (BM) in a space formed by etching the bonding oxide layer 140 and the capping layer 130, the first bonding metal layer 150 may be formed.

At S800, the second metal layer 160 may be deposited or placed on the first bonding metal layer 150 in a space formed by etching the bonding oxide layer 140 and the capping layer 130. In the example, the second metal layer 160 may be formed to contact the first bonding metal layer 150. In an embodiment, the second metal layer 160 may include copper (Cu).

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples of the disclosed technology are described and other implementations, enhancements and variations can be made based on what is described and illustrated in this patent document.

What is claimed is:

1. A method of manufacturing a semiconductor device, comprising:
forming a first metal layer;
forming a conductive layer on the first metal layer;
forming a capping layer on the conductive layer;
etching the first metal layer, the conductive layer, and the capping layer;
depositing a bonding oxide layer;
etching the bonding oxide layer and the capping layer;
forming a first bonding metal layer in an etched space; and
forming a second metal layer on the first bonding metal layer.

2. The method of claim 1,
wherein the first metal layer comprises aluminum (Al).

3. The method of claim 1,
wherein the conductive layer comprises titanium nitride (TiN).

4. The method of claim 1,
wherein the capping layer comprises nitride.

5. The method of claim 1,
wherein the second metal layer comprises copper (Cu).

6. A semiconductor device, comprising:
a lower substrate; and
an upper substrate bonded onto a top of the lower substrate,
wherein the lower substrate comprises:
a first metal layer;
a conductive layer formed on the first metal layer; and
a capping layer formed on the conductive layer.

7. The semiconductor device of claim 6,
wherein the lower substrate further comprises a bonding oxide layer formed in a space where the first metal layer, the conductive layer, and the capping layer are etched.

8. The semiconductor device of claim 7,
wherein the lower substrate further comprises a first bonding metal layer formed in a space where the bonding oxide layer and the capping layer are etched.

9. The semiconductor device of claim 8,
wherein the lower substrate further comprises a second metal layer formed on the first bonding metal layer.

10. A semiconductor device, comprising:
a substrate,
wherein the substrate comprises:
a first metal layer;
a conductive layer formed on the first metal layer, and
a capping layer formed on the conductive layer.

11. The semiconductor device of claim 10,
wherein, by a process of etching the first metal layer, the conductive layer, and the capping layer, the conductive layer is formed on a top surface of the first metal layer and not on a side surface of the first metal layer.

12. The semiconductor device of claim 11,
wherein, by the process of etching the first metal layer, the conductive layer, and the capping layer, the capping layer is formed above the first metal layer and not on a side surface of the first metal layer.

13. The semiconductor device of claim 10,
wherein the substrate further comprises a bonding oxide layer formed to contact a side surface of the first metal layer.

14. The semiconductor device of claim 13,
wherein the substrate further comprises a first bonding metal layer formed to contact the conductive layer, the capping layer, and the bonding oxide layer.

15. The semiconductor device of claim 14,
wherein the substrate further comprises a second metal layer formed to contact the first bonding metal layer.
